(19) United States
(12) Patent Application Publication
(10) Pub. No.: US 2024/0421694 A1
(43) Pub. Date: Dec. 19, 2024

(54) DRIVING CIRCUIT, DRIVING SYSTEM AND POWER CONVERSION DEVICE

(71) Applicant: ROHM CO., LTD., Kyoto-shi (JP)

(72) Inventor: Takaharu ISHIBASHI, Kyoto-shi (JP)

(21) Appl. No.: 18/815,088

(22) Filed: Aug. 26, 2024

Related U.S. Application Data
(63) Continuation of application No. PCT/JP2023/001906, filed on Jan. 23, 2023.

(30) Foreign Application Priority Data
Feb. 28, 2022 (JP) 2022-029029

(51) Int. Cl. H02M 1/088

(52) U.S. Cl. CPC H02M 1/088

(57) ABSTRACT

A driving circuit comprises: a driving voltage generation unit configured to, in a driving circuit that can drive a first semiconductor switching element (QL) including a first terminal, a second terminal, and a control terminal, supply a driving voltage (Vgl) to the control terminal to switch between on and off of the first semiconductor switching element; a comparator configured to compare a voltage (Vql) between the first terminal and the second terminal with a threshold voltage (Vth1); and a driving signal generation unit that generates a driving signal (Gsl′) to be input to the driving voltage generation unit on the basis of an output from the comparator and a first control signal (Gsl) that is generated by a control device and controls switching of the first semiconductor switching element.

### CROSS-REFERENCE TO RELATED APPLICATIONS

This application is a continuation under 35 U.S.C. § 120 of PCT/JP2023/001906 filed on Jan. 23, 2023, which is incorporated herein by reference, and claimed priority to Japanese Patent Application No. 2022-029029 filed on Feb. 28, 2022. The present application likewise claims priority under 35 U.S.C. § 119 to Japanese Application No. 2022-029029, filed Feb. 28, 2022, the entire content of which is also incorporated herein by reference.

### TECHNICAL FIELD

The present disclosure relates to a driving circuit.

### BACKGROUND ART

Conventionally, there has been a power conversion device equipped with a high side switching element (high side switch) and a low side switching element (low side switch) both connected between a power supply potential and a reference potential.

Technologies related to the above-described art are disclosed in, for example, Patent Document 1.

### CITATION LIST

### Patent Literature

Patent Document 1: JP No. 2021-150818

### BRIEF DESCRIPTION OF DRAWINGS

FIG. 1 is a diagram showing a configuration of a half bridge.

FIG. 2 is a timing chart showing an example of switching operations in the half bridge shown in FIG. 1.

FIG. 3 is a diagram showing a configuration of a gate driving system according to an exemplary embodiment of the disclosure.

FIG. 4 is a diagram showing a configurational example of a low side gate driving circuit.

FIG. 5 is a diagram showing a configurational example of a comparator.

FIG. 6 is a diagram showing a configurational example of a gate signal generation unit.

FIG. 7 is a diagram showing a configurational example of a high side gate driving circuit.

FIG. 8 is a timing chart showing one example of switching operations by the gate driving system according to an illustrative embodiment of the disclosure.

FIG. 9A is a diagram showing a configurational example of a voltage detection unit.

FIG. 9B is a diagram showing another configurational example of the voltage detection unit.

FIG. 10A is a diagram showing a first modification of a gate signal generation unit (low side).

FIG. 10B is a diagram showing a first modification of a gate signal generation unit (high side).

FIG. 10C is a timing chart showing operations by a configuration using the first modification of the gate signal generation unit.

FIG. 11 is a diagram showing a second modification of the gate signal generation unit.

FIG. 12 is a diagram showing a configurational example of a hold circuit.

FIG. 13 is a timing chart showing an operational example in the configuration shown in FIG. 12.

FIG. 14 is a timing chart showing another operational example in the configuration shown in FIG. 12.

FIG. 15 is a diagram showing a third modification of the gate signal generation unit.

FIG. 16 is a diagram showing a configurational example of a chopper.

### DESCRIPTION OF EMBODIMENTS

Hereinafter, an exemplary embodiment will be described with reference to the accompanying drawings.

### 1. PROBLEMS OF PRIOR ART

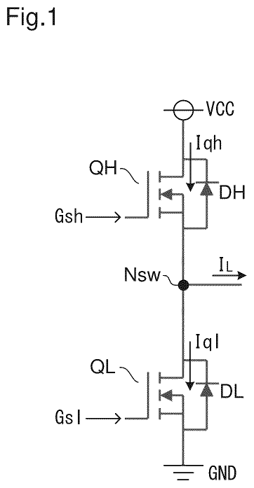

Before proceeding description of an embodiment of the present disclosure, problems of the prior art will be described. FIG. 1 is a diagram showing a configuration of a so-called half bridge. As shown in FIG. 1, the half bridge is composed of a high side switching element (high side arm element) QH and a low side switching element (low side arm element) QL. Half bridges are included in inverters, choppers or other power conversion devices.

The high side switching element QH and the low side switching element QL are provided by N-channel MOSFETs. The MOSFET is provided by SiC-MOSFET. In addition, MOSFETs made from semiconductor materials other than SiC may be used. The high side switching element QH may also be provided by P-channel MOSFET.

The high side switching element QH contains a body diode DH. The low side switching element QL contains a body diode DL.

The high side switching element QH and the low side switching element QL are connected in series between a power supply voltage VCC and a ground potential GND. The power supply voltage VCC is a DC voltage. More specifically, the drain of the high side switching element is connected to an application terminal of the power supply voltage VCC. The source of the high side switching element QH and the drain of the low side switching element QL are connected together at a node Nsw. The source of the low side switching element QL is connected to an application terminal of the ground potential.

The high side switching element QH is driven to turn on/off (switching driven) based on the high side gate signal Gsh. When the high side gate signal Gsh is at high level, the high side switching element QH is set to on-state; when the high side gate signal Gsh is at low level, the high side switching element QH is set to off-state.

The low side switching element QL is driven to turn on/off based on the low side gate signal Gsl. When the low side gate signal Gsl is at high level, the low side switching element QL is set to on-state; when the low side gate signal Gsl is at low level, the low side switching element QL is set to off-state.

In addition, the high side gate signal Gsh and the low side gate signal Gsl are outputted from an unshown control device.

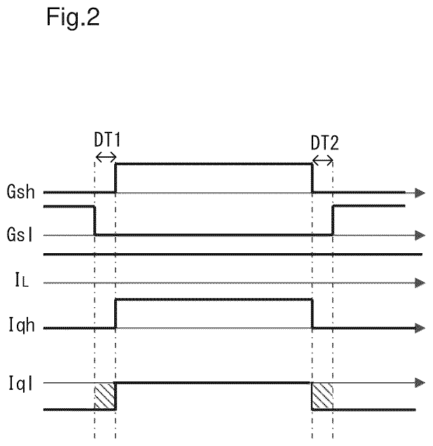

FIG. 2 is a timing chart showing an example of switching operations in the half bridge shown in FIG. 1. Shown in FIG. 2 are, in descending order from the uppermost stage, the high side gate signal Gsh, the low side gate signal Gsl, load current IL, high side element current Iqh, and low side element current Iql.

The load current IL is a current flowing through an unshown load connected to the node Nsw, where a direction from the node Nsw toward the load as shown in FIG. 1 is assumed as positive.

The high side element current Iqh is a current flowing through the high side switching element QH, where a direction from the power supply voltage VCC toward the node Nsw as shown in FIG. 1 is assumed as positive. In addition, the high side element current Iqh includes a current flowing through a channel region in the on-state high side switching element QH, as well as a current flowing through the body diode DH in the off-state high side switching element QH.

The low side element current Iql is a current flowing through the low side switching element QL, where a direction from the node Nsw toward the ground potential side as shown in FIG. 1 is assumed as positive. In addition, the low side element current Iql includes a current flowing through a channel region in the on-state low side switching element QL, and a current flowing through the body diode DL in the off-state low side switching element QL.

FIG. 2 shows a case in which the load current IL flows in the positive direction. As shown in FIG. 2, during a period from a timing of a high- to low-level transition of the low side gate signal Gsl until another timing of a low- to high-level transition of the high side gate signal Gsh, there is formed a first dead time DT1 in which the high side switching element QH and the low side switching element QL are set to off-state simultaneously. Also as shown in FIG. 2, during a period from a timing of a high- to low-level transition of the high side gate signal Gsh until another timing of a low- to high-level transition of the low side gate signal Gsl, there is formed a second dead time DT2 in which the high side switching element QH and the low side switching element QL are set to off-state simultaneously. In the first dead time DT1 and the second dead time DT2, the low side element current Iql (Iql in negative direction) flows through the body diode DL in the off-state low side switching element QL.

In addition, when the load current IL flows in the negative direction, the high side element current Iqh flows through the body diode DH in the high side switching element QH during the dead time.

As described above, conventionally, involvement of electrical conduction through body diodes of the switching elements in dead times would cause increases in loss or deteriorations of the switching elements (body-diode conduction deterioration).

### 2. CONFIGURATION OF GATE DRIVING SYSTEM

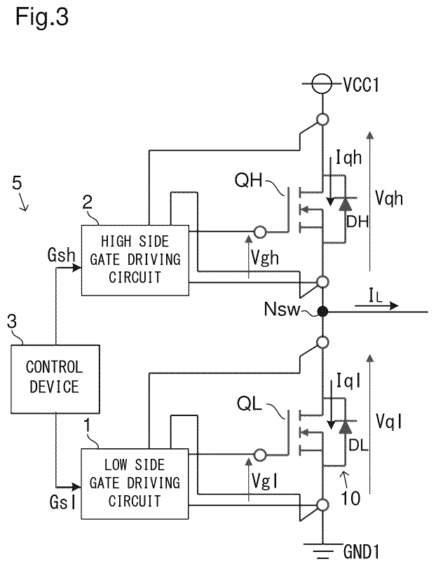

In view of the above-described conventional problems, technologies related to the present disclosure described below are implemented. FIG. 3 is a diagram showing a configuration of a gate driving system 5 according to an exemplary embodiment of the disclosure. The gate driving system 5 shown in FIG. 3 is configured to be enabled to drive gates of the high side switching element QH and the low side switching element QL, which compose a half bridge 10.

The half bridge 10 is identical in configuration to that of FIG. 1 described above, its detailed description being omitted here. The high side switching element QH and the low side switching element QL are connected in series between the power supply voltage VCC1 and the ground potential GND1.

The gate driving system 5 includes a low side gate driving circuit 1, a high side gate driving circuit 2, and a control device 3.

The control device 3 is configured to be enabled to output a high side gate control signal Gsh and a low side gate control signal Gsl. The low side gate control signal Gsl is a signal which is outputted to a low side gate driving circuit 1 and which is operable to control switching of the low side switching element QL. The high-level low side gate control signal Gsl is a signal operable to turn on the low side switching element QL, and the low-level low side gate control signal Gsl is a signal operable to turn off the low side switching element QL.

The high side gate control signal Gsh is a signal which is outputted to the high side gate driving circuit 2 and which is operable to control switching of the high side switching element QH. The high-level high side gate control signal Gsh is a signal operable to turn on the high side switching element QH, and the low-level high side gate control signal Gsh is a signal operable to turn off the high side switching element QH.

The low side gate driving circuit 1 generates a low side gate voltage Vgl on a basis of the inputted low side gate control signal Gsl and a drain-source voltage Vql of the low side switching element QL. The low side gate voltage Vgl is a voltage of the low side switching element QL referenced by a source potential (ground potential GND1), being applied to between gate and source of the low side switching element QL.

The high side gate driving circuit 2 generates a high side gate voltage Vgh on a basis of the inputted high side gate control signal Gsh and a drain-source voltage Vqh of the high side switching element QH. The high side gate voltage Vgh is a voltage of the high side switching element QH referenced by a source potential (potential of node Nsw), being applied to between gate and source of the high side switching element QH.

### 3. CONFIGURATION OF GATE DRIVING CIRCUIT

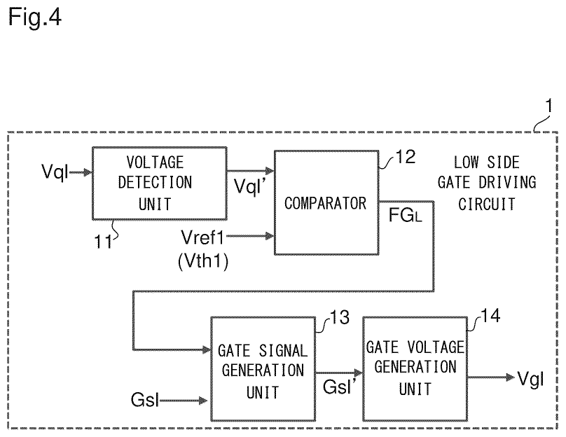

FIG. 4 is a diagram showing a configurational example of the low side gate driving circuit 1. The low side gate driving circuit 1 includes a voltage detection unit 11, a comparator 12, a gate signal generation unit 13, and a gate voltage generation unit 14. The voltage detection unit 11 is a circuit which is configured to detect a drain-source voltage Vql of the low side switching element QL, and which outputs a detected voltage Vql′ as a detection result. The comparator 12 compares the detected voltage Vql′ and the reference voltage Vref1 with each other to output a low side flag signal FG_{L} as a comparison result. Thus, the comparator 12 has a function of comparing the drain-source voltage Vql with a threshold voltage Vth1 corresponding to the reference voltage Vref1.

The gate signal generation unit 13 generates and outputs a low side gate signal Gsl′ on a basis of the low side flag signal FG_{L} and the low side gate control signal Gsl. The gate voltage generation unit 14 generates a low side gate voltage Vgl on a basis of the low side gate signal Gsl′, and outputs the generated signal to between gate and source of the low side switching element QL.

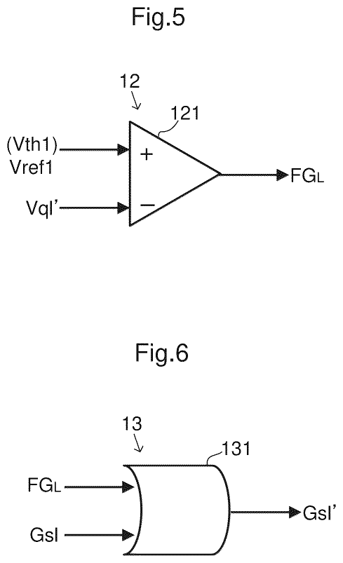

FIG. 5 is a diagram showing a configurational example of the comparator 12. As shown in FIG. 5, the comparator 12 is provided by a comparator 121. The reference voltage Vref1 is applied to a noninverting input terminal (+) of the comparator 121. A detected voltage Vql′ is applied to an inverting input terminal (−) of the comparator 121. The comparator 121 compares the reference voltage Vref1 and the detected voltage Vql′ with each other to output the low side flag signal FG_{L}.

When the low side element current Iql flows in the positive direction or the negative direction through the channel region of the on-state low side switching element QL, or when the low side element current Iql flows through the body diode DL of the low side switching element QL, the drain-source voltage Vql becomes lower than the threshold voltage Vth1. In this case, the detected voltage Vql′ becomes lower than the reference voltage Vref1, so that the low side flag signal FG_{L} outputted from the comparator 121 goes high level. Meanwhile, when no current flows through the low side switching element QL, the drain-source voltage Vql becomes equal to or higher than the threshold voltage Vth1. In this case, the detected voltage Vql′ becomes equal to or higher than the reference voltage Vref1, so that the low side flag signal FG_{L} outputted from the comparator 121 goes to low level.

As described above, the comparator 12 decides whether or not the low side switching element QL is conducting a current, regardless of the polarity of a current, and outputs a low side flag signal FG_{L} as a decision result.

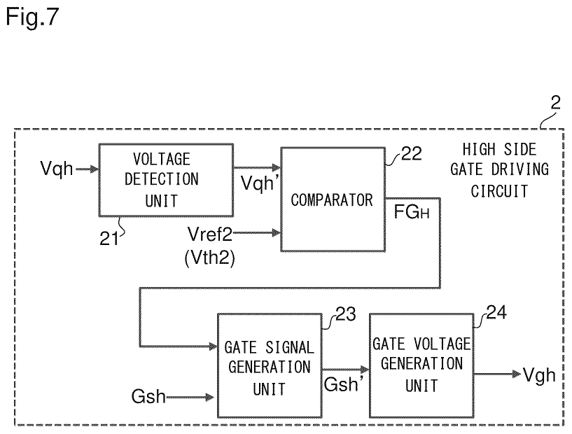

FIG. 6 is a diagram showing a configurational example of the gate signal generation unit 13. As shown in FIG. 6, the gate signal generation unit 13 includes an OR circuit 131. The OR circuit 131 takes a logical OR between the inputted low side flag signal FG_{L} and the low side gate control signal Gsl to output the low side gate signal Gsl′. That is, when at least one of the low side flag signal FG_{L} and the low side gate control signal Gsl is high, the low side gate signal Gsl′ goes high; when both the low side flag signal FG_{L} and the low side gate control signal Gsl are low, the low side gate signal Gsl′ goes low.

When the low side gate signal Gsl′ is high, the gate voltage generation unit 14 outputs the low side gate voltage Vgl operable to turn on the low side switching element QL; when the low side gate signal Gsl′ is low, the gate voltage generation unit 14 outputs the low side gate voltage Vgl operable to turn off the low side switching element QL.

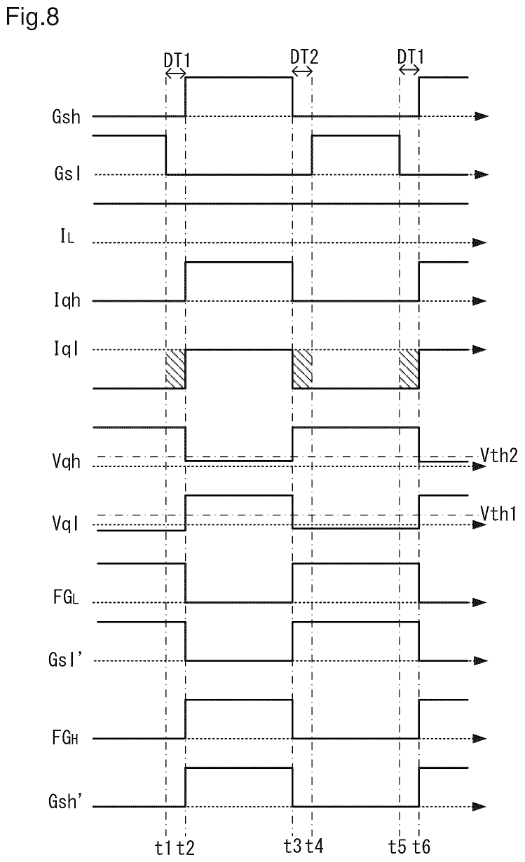

FIG. 7 is a diagram showing a configurational example of the high side gate driving circuit 2. The high side gate driving circuit 2 includes a voltage detection unit 21, a comparator 22, a gate signal generation unit 23, and a gate voltage generation unit 24.

The voltage detection unit 21 is a circuit operable to detect a drain-source voltage Vqh of the high side switching element QH and output a detected voltage Vqh′ as a detection result. The comparator 22 compares the detected voltage Vqh′ and a reference voltage Vref2 with each other to output a high side flag signal FG_{H} as a comparison result. Therefore, the comparator 22 has a function of comparing the drain-source voltage Vqh with a threshold voltage Vth2 corresponding to the reference voltage Vref2.

The gate signal generation unit 23 generates and outputs a high side gate signal Gsh′ on a basis of the high side flag signal FG_{H} and the high side gate control signal Gsh. The gate voltage generation unit 24 generates a high side gate voltage Vgh on a basis of the high side gate signal Gsh′ to output the generated signal to the gate of the high side switching element QH.

Concrete configurational examples of the comparator 22 and the gate signal generation unit 23 are similar to those of the comparator 12 and the gate signal generation unit 13 in the foregoing low side gate driving circuit 1, their detailed description being omitted. In addition, when the high side gate signal Gsh′ is high, the gate voltage generation unit 24 outputs the high side gate voltage Vgh operable to turn on the high side switching element QH; when the high side gate signal Gsh′ is low, the gate voltage generation unit 24 outputs the high side gate voltage Vgh operable to turn off the high side switching element QH.

### 4. SWITCHING OPERATIONS

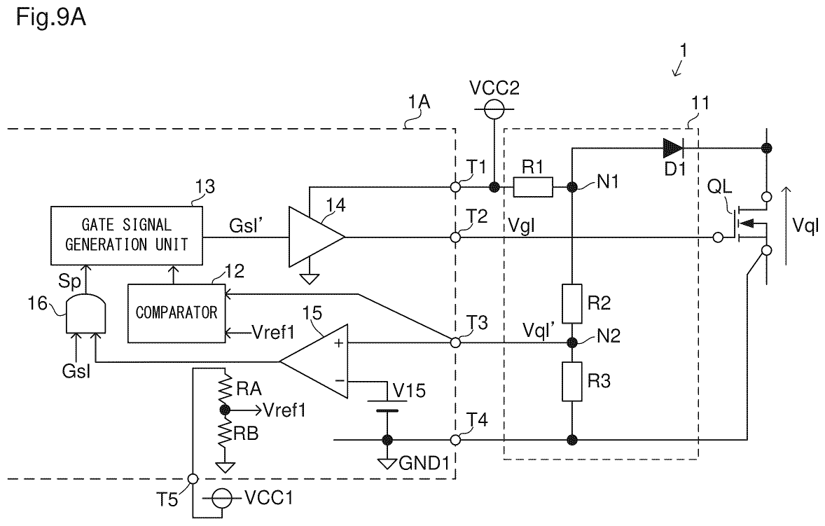

Next, switching operations by the gate driving system 5 of the above-described configuration will be described with reference to the timing chart shown in FIG. 8. Shown in FIG. 8, in descending order starting with the uppermost stage, are the high side gate control signal Gsh, the low side gate control signal Gsl, the load current IL, the high side element current Iqh, the low side element current Iql, the drain-source voltage Vqh of the high side switching element QH, the drain-source voltage Vql of the low side switching element QL, the low side flag signal FG_{L}, the low side gate signal Gsl′, the high side flag signal FG_{H}, and the high side gate signal Gsh′. It is noted that in FIG. 8, the threshold voltages Vth1, Vth2, although set to specified positive voltages as an example, are not limited to this.

As shown in FIG. 8, during a period from a timing t1 of a high- to low-level transition of the low side gate control signal Gsl until another timing t2 of a low- to high-level transition of the high side gate control signal Gsh, there is formed a first dead time DT1 in which both the low side gate control signal Gsl and the high side gate control signal Gsh go low level. That is, in this embodiment, a dead time as a control instruction from the control device 3 is provided.

Although the low side gate control signal Gsl is changed over from high to low level at the timing t1, the low side switching element QL keeps in a conducting state so that the low side flag signal FG_{L} is at high level, and the low side gate control signal Gsl′ outputted from the gate signal generation unit 13 is held at high level.

Accordingly, from the timing t1 on, the on-state of the low side switching element QL is maintained. Then, when the high side gate control signal Gsh is changed over from low- to high-level at the timing t2, the high side gate signal Gsh′ is changed to high level by the gate signal generation unit 23. As a result, the high side switching element QH is turned on. In this case, the drain-source voltage Vqh of the high side switching element QH becomes lower than the threshold voltage Vth2, causing the high side flag signal FG_{H} outputted from the comparator 22 to go high level. Meanwhile, the drain-source voltage Vql of the low side switching element QL becomes nearly equal to power supply voltage VCC1 (e.g., 100 V), being higher than the threshold voltage Vth1, while the low side flag signal FG_{L} outputted from the comparator 12 goes low level. Accordingly, the low side gate signal Gsl′ goes low level, and the low side switching element QL is turned off.

As described above, in the period of the first dead time DT1 as a control instruction, the low side switching element QL is controlled so as to be under the on-state, leading to suppression (simultaneous off-state of both high side and low side switching elements) of the dead time in actual control process, so that current flow through the body diode DL can be suppressed.

As shown in FIG. 8, during a period from a timing t3 of a high- to low-level transition of the high side gate control signal Gsh until another timing t4 of a low- to high-level transition of the low side gate control signal Gsl, there is formed a second dead time DT2 in which both the low side gate control signal Gsl and the high side gate control signal Gsh go low level. That is, as in the case of the first dead time DT1, the second dead time DT2 as a control instruction from the control device 3 is provided.

At the timing t3, the high side gate control signal Gsh is changed over from high- to low-level, so that the high side switching element QH is turned off, and the load current IL commutates to the low side switching element QL. Accordingly, at the timing t3, the drain-source voltage Vql of the low side switching element QL becomes lower than the threshold voltage Vth1, causing the low side flag signal FG_{L} outputted from the comparator 12 to be changed from low- to high-level. Then, the low side gate signal Gsl′ goes high level, causing the low side switching element QL to be turned on.

Accordingly, from the timing t3 on, the on-state of the low side switching element QL is maintained, so that no current passes through the body diode DL of the low side switching element QL. Thus, it is expectable to suppress occurrence of loss.

As described above, in the period of the second dead time DT2 as a control instruction, the low side switching element QL is controlled so as to be under the on-state, leading to suppression of the dead time in actual control process, so that current flow through the body diode DL can be suppressed.

Accordingly, in this embodiment, dead time is suppressed in terms of actual control, so that reduction of loss and suppression of switching element deterioration can be fulfilled. Further, control precision for the power conversion device can be enhanced.

### 5. VOLTAGE DETECTION UNIT

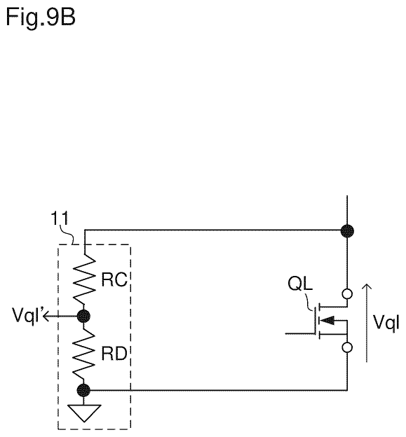

Next, a concrete configurational example of the voltage detection unit 11, 21 will be described. Here is explained, typically, a configuration of the voltage detection unit 11 corresponding to the low side switching element QL. FIG. 9A is a diagram showing a configurational example of the voltage detection unit 11. Shown in FIG. 9A is a configuration of the voltage detection unit 11 and a gate driver IC 1A in correspondence to the low side switching element QL. The low side gate driving circuit 1 includes the voltage detection unit 11 and the gate driver IC 1A.

As shown in FIG. 9A, the voltage detection unit 11 includes resistors R1 to R3, and a diode D1. A cathode of the diode D1 is connected to the drain of the low side switching element QL. An anode of the diode D1 is connected to one end of the resistor R2 in a node N1. The other end of the resistor R2 is connected to one end of the resistor R3 in a node N2. The other end of the resistor R3 is connected to the source (application terminal of ground potential GND1) of the low side switching element QL. One end of the resistor R1 is connected to an application terminal of a power supply voltage VCC2. The other end of the resistor R1 is connected to the node N1.

The gate driver IC 1A is made up by integrating together, in one chip, the comparator 12, the gate signal generation unit 13, the gate voltage generation unit 14, a comparator 15, and an AND circuit 16. Also, the gate driver IC 1A has terminals T1 to T5 operable to establish electrical connections with the external. The voltage detection unit 11 and the low side switching element QL are placed outside the gate driver IC 1A.

The node N2 is connected to a noninverting input terminal (+) of the comparator 15 via the terminal T3. The other end of the resistor R3 and the source of the low side switching element QL are connected to the terminal T4. A reference voltage V15 referenced by a potential (ground potential GND1) of the terminal T4 is applied to the inverting input terminal (−) of the comparator 15. The comparator 15 compares a detected voltage Vql′ occurring at the node N2 with the reference voltage V15 to output a comparison result to one input terminal of the AND circuit 16. A low side gate control signal Gsl is inputted to the other input terminal of the AND circuit 16. The AND circuit 16 outputs a protection signal Sp to the gate signal generation unit 13.

The detected voltage Vql′ applied to the terminal T3 is inputted also to the comparator 12 so as to be compared with the reference voltage Vref1 by the comparator 12.

On a basis of the low side gate signal Gsl′ generated by the gate signal generation unit 13, the gate voltage generation unit 14 outputs the low side gate voltage Vgl from the terminal T2 to the gate of the low side switching element QL while switching the low side gate voltage Vgl between the power supply voltage VCC2 applied to the terminal T1 and the potential of the terminal T4 (ground potential GND1).

When the low side switching element QL is in an on-state or when a current flows through the body diode DL of the low side switching element QL, the drain-source voltage Vql of the low side switching element QL lowers while the cathode voltage of the diode D1 lowers. As a result, the anode voltage of the diode D1 also lowers, and the detected voltage Vql′ results in a partial voltage resulting from dividing the anode voltage (voltage occurring at the node N1), which is a low voltage, by the resistors R2, R3.

Meanwhile, when the low side switching element QL has short-circuited, the cathode voltage of the diode D1 increases, so that the anode voltage of the diode D1 also increases, with the detected voltage Vql′ as well increasing. When the detected voltage Vql′ increases over the reference voltage V15, the protection signal Sp goes to high level, where a protective operation is executed.

According to such a voltage detection unit 11, the detected voltage Vql′ for use in the comparator 12 as well as for use of the short-circuit protective function can be detected, so that increases in circuit size as well as cost increases can be suppressed.

The voltage detection unit 11 may also be configured, for example, as shown in FIG. 9B. The voltage detection unit 11 shown in FIG. 9B divides the drain-source voltage Vql of the low side switching element QL by voltage-dividing resistors RC, RD to generate the detected voltage Vql′.

### 6. SETTING OF THRESHOLD VOLTAGES

Setting of the threshold voltages Vth1, Vth2 (FIG. 8) may appropriately be attained by satisfying that Vth1, Vth2<VCC1 (e.g., 100 V).

For example, as shown in FIG. 9A, the reference voltage Vref1 to be used for comparisons in the comparator 12 may be generated by dividing the power supply voltage VCC1 (see FIG. 3) applied to the terminal T5 by means of voltage-dividing resistors RA, RB. The voltage-dividing resistors RA, RB are contained in the gate driver IC 1A. In addition, the voltage-dividing resistors RA, RB may be provided outside the gate driver IC 1A, and the generated reference voltage Vref1 may be inputted via a terminal to inside the gate driver IC 1A.

In addition, as described later, the comparators 12, 22 may decide only electrical conduction of the body diodes DH, DL as electrical conduction of the switching elements QH, QL. In this case, the threshold voltages Vth1, Vth2 may appropriately be set to voltages which are higher than the drain-source voltage Vqh, Vql (negative voltages) for electrical conduction of the body diodes DH, DL, and which are lower than the drain-source voltages Vqh, Vql (negative voltages) for electrical conduction of the on-state switching elements QH, QL. That is, the threshold voltages Vth1, Vth2 are set to negative voltages.

### 7. FIRST MODIFICATION OF GATE SIGNAL GENERATION UNIT

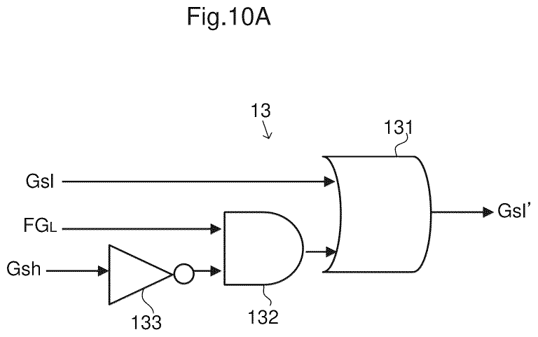

FIG. 10A is a diagram showing a first modification of the gate signal generation unit 13. The gate signal generation unit 13 shown in FIG. 10A includes the OR circuit 131, an AND circuit 132, and an inverter 133.

A high side gate control signal Gsh is inputted to the inverter 133. A low side flag signal FG_{L} and an output of the inverter 133 are inputted to the AND circuit 132. The AND circuit 132 takes a logical AND between the low side flag signal FG_{L} and a signal resulting from logically inverting the high side gate control signal Gsh. The low side gate control signal Gsl and an output of the AND circuit 132 are inputted to the OR circuit 131. The OR circuit 131 takes a logical OR between the low side gate control signal Gsl and an output of the AND circuit 132 to output the low side gate signal Gsl′.

FIG. 10B is a diagram showing a first modification of the gate signal generation unit 23. The gate signal generation unit 23 shown in FIG. 10B includes an OR circuit 231, an AND circuit 232, and an inverter 233.

A low side gate control signal Gsl is inputted to the inverter 233. A high side flag signal FG_{H} and an output of the inverter 233 are inputted to the AND circuit 232. The AND circuit 232 takes a logical AND between the high side flag signal FG_{H} and a signal resulting from logically inverting the low side gate control signal Gsl by means of the inverter 233. The high side gate control signal Gsh and an output of the AND circuit 232 are inputted to the OR circuit 231. The OR circuit 231 takes a logical OR between the high side gate control signal Gsh and an output of the AND circuit 232 to output a high side gate signal Gsh′.

As shown in FIG. 8 described above, at the timing t2 when the high side gate control signal Gsh has changed over from low- to high-level, the low side flag signal FG_{L} holds high level until the drain-source voltage Vql of the low side switching element QL shows an increase. Therefore, with the configuration of FIG. 6 described above, since the low side gate signal Gsl′ holds high level while the low side flag signal FG_{L} holds high level, there is a possibility that simultaneous on-state of the switching elements QH, QL can occur.

In this connection, FIG. 10C is a timing chart showing operations of the gate driving system 5 using the configuration shown in FIG. 10A and FIG. 10B. In the configuration shown in FIG. 10A and FIG. 10B, at the timing t2 when the high side gate control signal Gsh has changed over from low- to high-level, a signal outputted from the AND circuit 132 is immediately set to low level, regardless of the low side flag signal FG_{L}, and the low side gate signal Gsl′ is set to low level. Accordingly, simultaneous on-state of the switching elements QH, QL can be suppressed. Also, from the timing t2 on, since the high side gate control signal Gsh keeps high level even though the low side flag signal FG_{L} has changed from low- to high-level due to noise or the like, the output of the AND circuit 132 is held low level while the low side gate signal Gsl′ is held low level. As a result of this, occurrence of simultaneous on-state due to the low side switching element QL being turned on can be suppressed.

At the timing t3, since the high side switching element QH keeps on-state and conducting state, the high side flag signal FG_{H} is at high level. Meanwhile, at the timing t3, the gate control signal Gsh of the high side switching element QH is changed over from high- to low-level. However, since the gate control signal Gsl of the low side switching element QL inputted to the inverter 233 is still at low level, a high-level signal is inputted to the AND circuit 232, so that the logical AND outputted from the AND circuit 232 goes high level. Accordingly, the high side gate signal Gsh′, which is a logical OR outputted from the OR circuit 231, keeps high level, so that the high side switching element QH keeps on-state.

Further, at the timing t4, since the low side gate control signal Gsl is changed over from low- to high-level regardless of the high side flag signal FG_{H}, the signal outputted from the AND circuit 232 is immediately changed over to low level. Thus, at the timing t4, the high side gate signal Gsh′ is immediately set to low level. As a result of this, occurrence of simultaneous on-state with the low side switching element QL, which is caused by the high side switching element QH keeping on-state can be suppressed.

### 8. SECOND MODIFICATION OF GATE SIGNAL GENERATION UNIT

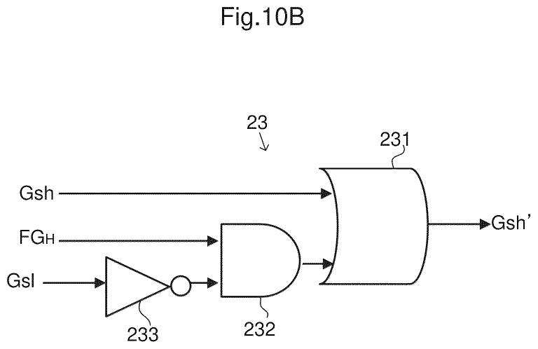

FIG. 11 is a diagram showing a second modification of the gate signal generation unit 13. The gate signal generation unit 13 shown in FIG. 11 includes an OR circuit 131, and a hold circuit 134.

The low side flag signal FG_{L} and the high side gate control signal Gsh are inputted to the hold circuit 134. The hold circuit 134 holds high-level output with a trigger given by the low side flag signal FG_{L} having risen from low- to high-level, and moreover resets its output to low level by the high side gate control signal Gsh as a reset signal having risen from low- to high-level. The low side gate control signal Gsl and an output of the hold circuit 134 are inputted to the OR circuit 131. The OR circuit 131 takes a logical OR of the low side gate control signal Gsl and the output of the hold circuit 134 to output a low side gate signal Gsl′.

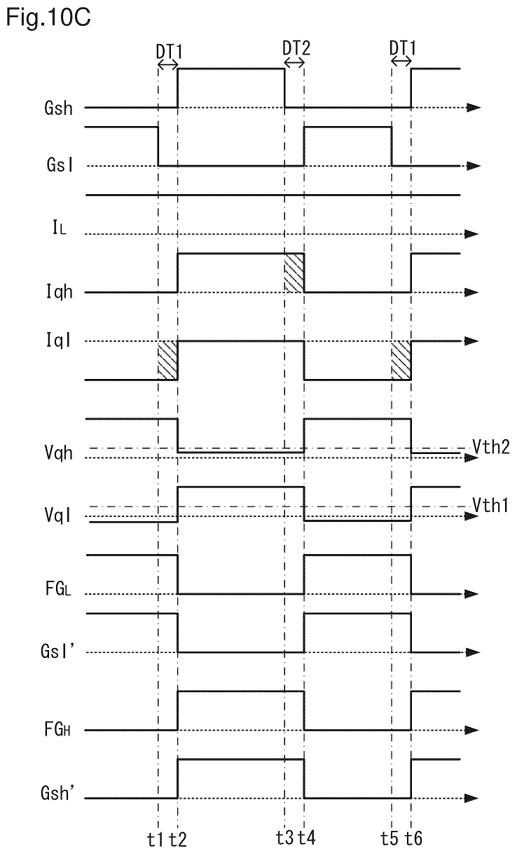

FIG. 12 is a diagram showing a configurational example of the hold circuit 134. As shown in FIG. 12, the hold circuit 134 is provided by an RS flip-flop 1341. A low side flag signal FG_{L} is inputted to a set terminal of the RS flip-flop 1341. A high side gate control signal Gsh is inputted to a reset terminal of the RS flip-flop 1341. A Q output is outputted from a Q output terminal of the RS flip-flop 1341.

In FIG. 8 described above, after the low side flag signal FG_{L} has gone high level at the timing t4, the low side switching element QL is turned off when the low side flag signal FG_{L} is changed over to low level due to noise in the dead time DT1, with a result that a current flow through the body diode DL can occur. Accordingly, a configuration shown in FIG. 11 (FIG. 12) is adopted.

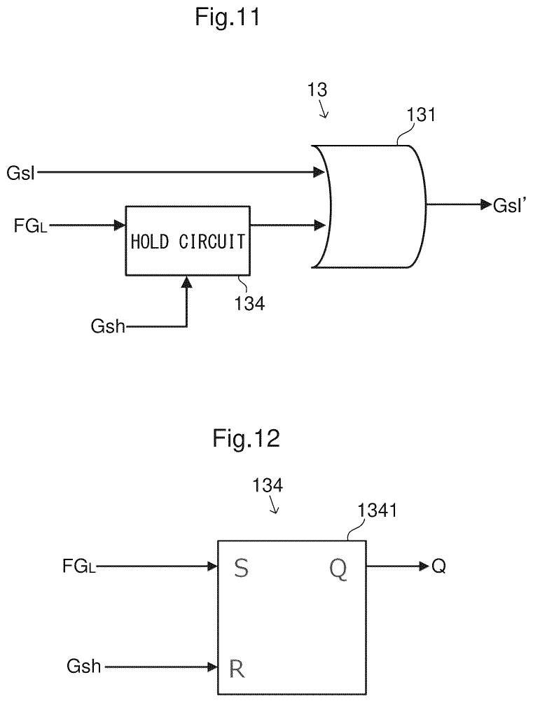

FIG. 13 is a timing chart showing an operational example in the configuration shown in FIG. 12. Shown in FIG. 13 are, in descending order from the uppermost stage, the low side flag signal FG_{L}, the high side gate control signal Gsh, and the Q output. As shown in FIG. 13, at a timing t11 (timing t4 in FIG. 8) when the low side flag signal FG_{L} has risen from low- to high-level, the RS flip-flop 1341 is set, causing the Q output to rise to high level. Thereafter, as shown in FIG. 13, even though the low side flag signal FG_{L} has fallen to low level due to noise, the Q output is held at high level. Accordingly, the low side gate signal Gsl′ is held at high level, so that turn-off of the low side switching element QL can be suppressed. Then, as shown in FIG. 13, at the timing t13 (timing t6 in FIG. 8) when the high side gate control signal Gsh has risen to high level, the RS flip-flop 1341 is reset, so that the Q output is set to low level. Accordingly, in the dead time DT1, the Q output is held at high level, so that turn-off of the low side switching element QL, which leads to a current flow through the body diode DL, can be suppressed. Further, at a timing when the high side gate control signal Gsh has risen to high level, the Q output is set to low level and the low side gate signal Gsl′ is set to low level, so that turn-off of the low side switching element QL and simultaneous on-state of the high side switching element QH and the low side switching element QL can be suppressed.

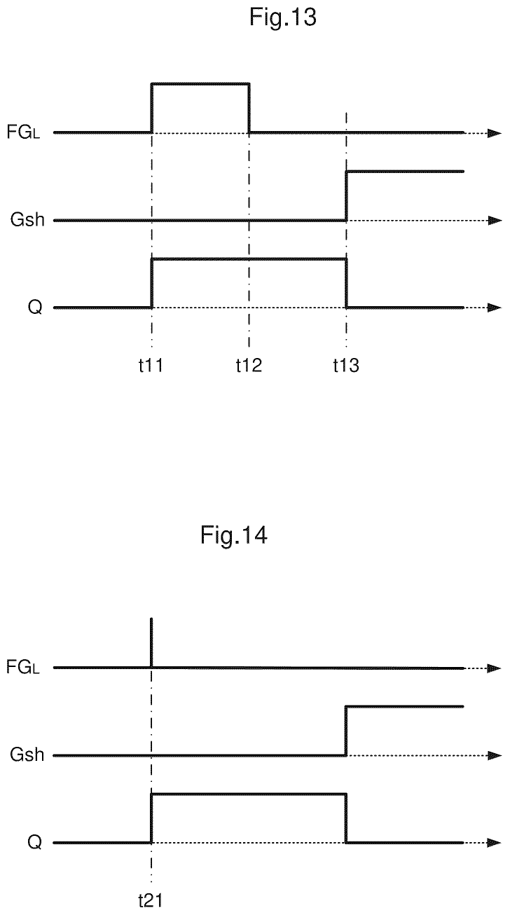

Also, as described above, the configuration shown in FIG. 11 is effective even when the threshold voltage Vth1 is set to a negative voltage so that only the electrical conduction through the body diode DL is decided as electrical conduction. An operational example in the configuration shown in FIG. 12 in this case is shown in the timing chart of FIG. 14. Kinds of signals shown in FIG. 14 are similar to those of FIG. 13.

At a timing t5 when the low side gate control signal Gsl is changed over from high- to low-level in FIG. 8 (in this case, however, the low side flag signal FG_{L} is at low level), the low side switching element QL is turned off, causing a current to flow through the body diode DL, with a result that the drain-source voltage Vql becomes lower than the threshold voltage Vth1. As a result of this, the low side flag signal FG_{L} goes high level (timing t21 in FIG. 14). Consequently, the low side switching element QL is turned on. Then, the drain-source voltage Vql becomes higher than the threshold voltage Vth1, causing the low side flag signal FG_{L} to go immediately to low level. However, the RS flip-flop 1341 is set at the timing t21, so that the Q output is held at high level.

### 9. THIRD MODIFICATION OF GATE SIGNAL GENERATION UNIT

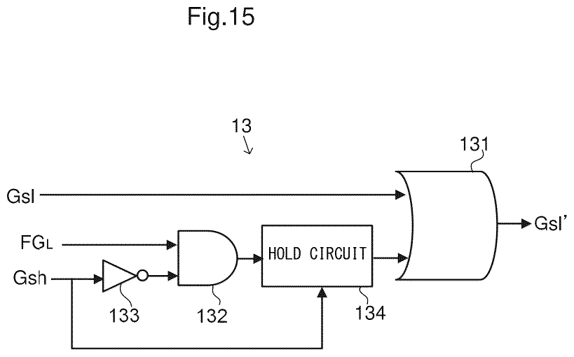

FIG. 15 is a diagram showing a third modification of the gate signal generation unit 13. This modification has a configuration in which the first modification and the second modification described above are combined together. More specifically, the configuration shown in FIG. 15 differs from the second modification (FIG. 11) in that the AND circuit 132 and the inverter 133 are provided. The low side flag signal FG_{L} as well as a signal obtained by logically inverting the high side gate control signal Gsh by means of the inverter 133 are inputted to the AND circuit 132, and an output of the AND circuit 132 is inputted to a set terminal of the hold circuit 134. With such a configuration, effects of both the first modification and the second modification described above can be enjoyed.

### 10. POWER CONVERSION DEVICE

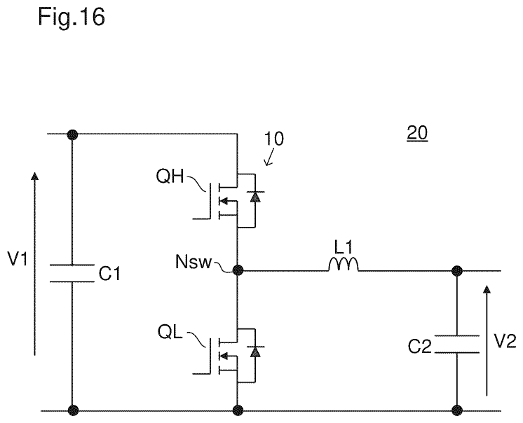

The gate driving system 5 and the half bridge 10 according to the present disclosure as described above are applicable to various types of power conversion devices. FIG. 16 is a diagram showing a configuration of a chopper 20 as an example of the power conversion device. The chopper 20 is referred to also as bidirectional DC/DC converter or bidirectional chopper.

The chopper 20 includes a half bridge 10 made up of a high side switching element QH and a low side switching element QL, capacitors C1, C2, and an inductor L1. The capacitor C1 is connected across the half bridge 10. A node Nsw, to which the high side switching element QH and the low side switching element QL are connected, is connected to one end of the inductor L1. The capacitor C2 is connected between the other end of the inductor L1 and a lower-potential side of the half bridge 10.

A voltage V1 across the capacitor C1 is higher than a voltage V2 across the capacitor C2 (V1>V2). For power conversion from V1 to V2, the chopper 20 operates as a buck chopper; for power conversion from V2 to V1, the chopper 20 operates as a boost chopper.

In addition, the gate driving system 5 and the half bridge 10 according to the present disclosure are applicable not only to choppers but also to inverters or other power conversion devices. In a case where the power conversion device is a three-phase inverter as an example, three half bridges 10 are provided.

### 11. OTHERS

It should be noted that various technical features disclosed herein may be embodied not only as in the above-described embodiment but also as changed or modified in various ways without departing the gist of the disclosure's technical creation. That is, the above-described embodiment should be construed as not being limitative but being an exemplification at all points. The technical scope of the disclosure should be defined by the appended claims, and it should be construed that all changes and modifications equivalent in sense and scope to the appended claims are included in the technical scope of the disclosure.

### 12. APPENDICES

As described hereinabove, for example, a driving circuit (1) according to one aspect of the present disclosure is a driving circuit which is operable to drive a first semiconductor switching element (QL) including a first terminal, a second terminal, and a control terminal, the driving circuit comprising:
a driving voltage generation unit (14) configured to supply a driving voltage (Vgl) to the control terminal so as to change over between on and off state of the first semiconductor switching element,
a comparator (12) configured to compare a voltage (Vql) between the first terminal and the second terminal with a threshold voltage (Vth1); and
a driving signal generation unit (13) configured to generate a driving signal (Gsl′) to be inputted to the driving voltage generation unit on a basis of an output of the comparator and a first control signal (Gsl) which is generated by the control device (3) to control switching of the first semiconductor switching element (first configuration, FIG. 4).

Also, in the foregoing first configuration, the driving signal generation unit (13) may include a first OR circuit (131) to which an output (FG_{L}) of the comparator (12) and the first control signal (Gsl) are inputted and which outputs the driving signal (Gsl′) (second configuration, FIG. 6).

Also, in the first configuration, the driving signal generation unit (13) may include: an inverter (133) so configured that a second control signal (Gsh) operable to control switching of a second semiconductor switching element (QH) connected to the first terminal or the second terminal of the first semiconductor switching element (QL) is inputted to the inverter,
an AND circuit (132) so configured that an output (FG_{L}) of the comparator and an output of the inverter are inputted to the AND circuit; and
a second OR circuit (131) to which the first control signal (Gsl) and an output of the AND circuit are inputted and which outputs the driving signal (Gsl′) (third configuration, FIG. 10A).

Also, in the first configuration, the driving signal generation unit (13) may include: a hold circuit (134) configured to hold an output signal (Q) of high level with a rising edge of an output (FG_{L}) of the comparator used as a trigger and to reset the output signal to low level with a rising edge of a second control signal (Gsh) operable to control switching of a second semiconductor switching element connected to the first terminal or the second terminal of the first semiconductor switching element; and a third OR circuit (131) to which the first control signal (Gsl) and the output signal are inputted (fourth configuration, FIG. 11).

Also, in the fourth configuration, the threshold voltage (Vth1) is so set that only electrical conduction of a body diode (DL) in the first semiconductor switching element is decided by the comparator as electrical conduction of the first semiconductor switching element (fifth configuration).

Also, in the first configuration, the driving signal generation unit (13) may include:
an inverter (133) so configured that a second control signal (Gsh) operable to control switching of a second semiconductor switching element connected to the first terminal or the second terminal of the first semiconductor switching element is inputted to the inverter,
an AND circuit (132) so configured that an output of the comparator and an output of the inverter are inputted to the AND circuit,
a hold circuit (134) configured to hold an output signal of high level with a rising edge of an output of the AND circuit used as a trigger and to reset the output signal to low level with a rising edge of the second control signal with a rising edge of the second control signal used as a trigger; and
a third OR circuit (131) to which the first control signal and the output signal are inputted (sixth configuration, FIG. 15).

Also, in any one of the first to sixth configurations, the driving circuit may further comprise a voltage detection unit (11) configured to detect a voltage between the first terminal and the second terminal, wherein
the comparator is configured to compare a detected voltage (Vql′) as a detection result by the voltage detection unit with a reference voltage (Vref1) corresponding to the threshold voltage (seventh configuration, FIG. 4).

Also, in the seventh configuration, the voltage detection unit (11) may include:
a diode (D1) having a cathode connectable to a first terminal of the first semiconductor switching element,
a first resistor (R1) having a first terminal connectable to an application terminal of a power supply voltage (VCC2); and
a second resistor (R2) having a first terminal connectable to a first node at which an anode of the diode and a second terminal of the first resistor are connected together (eighth configuration, FIG. 9A).

Also, in the seventh configuration, the voltage detection unit (11) has a voltage-dividing resistor (RC, RD) connected between the first terminal and the second terminal (ninth configuration, FIG. 9B).

Also, in any one of the first to ninth configurations, the threshold voltage may be set on a basis of a DC voltage (VCC1) applied to a half bridge including the first semiconductor switching element (tenth configuration, FIG. 9A).

Also, in the tenth configuration, the driving circuit may further comprise a voltage-dividing resistor (RA, RB) operable to divide the DC voltage for setting of the threshold voltage (eleventh configuration, FIG. 9A).

Also, in the eleventh configuration, the driving circuit may further comprise a driver IC (1A) configured by integrating together the driving voltage generation unit, the comparator, and the driving signal generation unit, wherein the voltage-dividing resistor is contained in the driver IC (twelfth configuration, FIG. 9A).

Also, in the eleventh configuration, the driving circuit may further comprise a driver IC configured by integrating together the driving voltage generation unit, the comparator, and the driving signal generation unit, wherein the voltage-dividing resistor is provided outside the driver IC (thirteenth configuration).

Further, a driving system (5) according to one aspect of the present disclosure comprises: the driving circuit according to any one of the first to thirteenth configurations; and the control device (fourteenth configuration, FIG. 3).

Further, a power conversion device (20) according to one aspect of the present disclosure comprises: the driving system (5) of the fourteenth configuration; and a half bridge (10) including the first semiconductor switching element (fifteenth configuration, FIG. 15).

### INDUSTRIAL APPLICABILITY

The present disclosure is applicable, for example, to various types of power conversion devices.

### REFERENCE SIGNS LIST

1 low side gate driving circuit
1A gate driver IC
2 high side gate driving circuit
3 control device
5 gate driving system
10 half bridge
11 voltage detection unit
12 comparator
13 gate signal generation unit
14 gate voltage generation unit
15 comparator
16 AND circuit
20 chopper
21 voltage detection unit
22 comparator
23 gate signal generation unit
24 gate voltage generation unit
121 comparator
131, 231 OR circuit
132, 232 AND circuit
133, 233 inverter
134 hold circuit
1341 RS flip-flop
C1, C2 capacitor
D1 diode
DH, DL body diode
L1 inductor
QH high side switching element
QL low side switching element
R1 to R3 resistor
RA, RB, RC, RD voltage-dividing resistor
T1 to T5 terminal

1. A driving circuit which is operable to drive a first semiconductor switching element including a first terminal, a second terminal, and a control terminal, the driving circuit comprising:
a driving voltage generation unit configured to supply a driving voltage to the control terminal so as to change over between on and off state of the first semiconductor switching element;
a comparator configured to compare a voltage between the first terminal and the second terminal with a threshold voltage; and
a driving signal generation unit configured to generate a driving signal to be inputted to the driving voltage generation unit on a basis of an output of the comparator and a first control signal which is generated by the control device to control switching of the first semiconductor switching element.

2. The driving circuit according to claim 1, wherein
the driving signal generation unit includes a first OR circuit to which an output of the comparator and the first control signal are inputted and which outputs the driving signal.

3. The driving circuit according to claim 1, wherein
the driving signal generation unit includes:
an inverter so configured that a second control signal operable to control switching of a second semiconductor switching element connected to the first terminal or the second terminal of the first semiconductor switching element is inputted to the inverter;
an AND circuit so configured that an output of the comparator and an output of the inverter are inputted to the AND circuit; and
a second OR circuit to which the first control signal and an output of the AND circuit are inputted and which outputs the driving signal.

4. The driving circuit according to claim 1, wherein
the driving signal generation unit includes:
a hold circuit configured to hold an output signal of high level with a rising edge of an output of the comparator used as a trigger and to reset the output signal to low level with a rising edge of a second control signal operable to control switching of a second semiconductor switching element connected to the first terminal or the second terminal of the first semiconductor switching element; and
a third OR circuit to which the first control signal and the output signal are inputted.

5. The driving circuit according to claim 4, wherein
the threshold voltage is so set that only electrical conduction of a body diode in the first semiconductor switching element is decided by the comparator as electrical conduction of the first semiconductor switching element.

6. The driving circuit according to claim 1, wherein
the driving signal generation unit includes:
an inverter so configured that a second control signal operable to control switching of a second semiconductor switching element connected to the first terminal or the second terminal of the first semiconductor switching element is inputted to the inverter;
an AND circuit so configured that an output of the comparator and an output of the inverter are inputted to the AND circuit;
a hold circuit configured to hold an output signal of high level with a rising edge of an output of the AND circuit used as a trigger and to reset the output signal to low level with a rising edge of the second control signal with a rising edge of the second control signal used as a trigger; and
a third OR circuit to which the first control signal and the output signal are inputted.

7. The driving circuit according to claim 1, further comprising a voltage detection unit configured to detect a voltage between the first terminal and the second terminal, wherein
the comparator is configured to compare a detected voltage as a detection result by the voltage detection unit with a reference voltage corresponding to the threshold voltage.

8. The driving circuit according to claim 7, wherein
the voltage detection unit includes:
a diode having a cathode connectable to a first terminal of the first semiconductor switching element;
a first resistor having a first terminal connectable to an application terminal of a power supply voltage; and
a second resistor having a first terminal connectable to a first node at which an anode of the diode and a second terminal of the first resistor are connected together.

9. The driving circuit according to claim 7, wherein the voltage detection unit has a voltage-dividing resistor connected between the first terminal and the second terminal.

10. The driving circuit according to claim 1, wherein the threshold voltage is set on a basis of a DC voltage applied to a half bridge including the first semiconductor switching element.

11. The driving circuit according to claim 10, further comprising a voltage-dividing resistor operable to divide the DC voltage for setting of the threshold voltage.

12. The driving circuit according to claim 11, further comprising a driver IC configured by integrating together the driving voltage generation unit, the comparator, and the driving signal generation unit, wherein
the voltage-dividing resistor is contained in the driver IC.

13. The driving circuit according to claim 11, further comprising a driver IC configured by integrating together the driving voltage generation unit, the comparator, and the driving signal generation unit, wherein
the voltage-dividing resistor is provided outside the driver IC.

14. A driving system comprising: the driving circuit according to claim 1; and the control device.

15. A power conversion device comprising: the driving system according to claim 14; and a half bridge including the first semiconductor switching element.
